(19) United States
(12) Patent Application Publication
(10) Pub. No.: US 2019/0086453 A1
(43) Pub. Date: Mar. 21, 2019

(54) Method, System and Computer Program Product for Transmitting Consumption Information to a User

(71) Applicants: Christopher McLachlan, Köln (DE); Sukhjinder Singh, Orinda, CA (US); Peter Shiau, San Francisco, CA (US)

(72) Inventors: Christopher McLachlan, Köln (DE); Sukhjinder Singh, Orinda, CA (US); Peter Shiau, San Francisco, CA (US)

(73) Assignee: innogy New Ventures LLC, Palo Alto, CA (US)

(21) Appl. No.: 15/709,219

(22) Filed: Sep. 19, 2017

(51) Int. Cl. G01R 21/133; G01R 11/56

(52) U.S. Cl. CPC G01R 21/133; G06Q 50/06; G01R 11/56

(57) ABSTRACT

Provided is a method for transmitting energy consumption information to a user comprising, obtaining consumption data from at least one source, extracting consumption information from the obtained consumption data, and transmitting the extracted consumption information to the user. At least a communication channel for transmitting the consumption information to a user is selected from a set of different communication channels based on stored information extracted from previous exchange of the consumption information.

### FIELD OF THE INVENTION

The subject-matter relates to a method for transmitting consumption information to a user. Moreover, the subject-matter relates to a system arranged for transmitting consumption information to a user. The subject-matter also relates to a computer program product comprising instructions for causing a processor to transmit consumption information to a user.

### BACKGROUND OF THE INVENTION

As devices become increasingly available online, and able to report on their own status, more and more data is available for consumers. Not only data provided by the devices as such, but in addition also data provided by service providers, for instance in the form of invoices or bills are available to user. These data are available in different formats, for instance as a pdf document, via a website or provided through Application Programming Interfaces (or APIs) for direct access using computer programs.

This is especially true in the energy industry, where utilities provide more and more so called “smart meters”. These smart meters are capable of measuring the energy consumption of users. Energy consumption could be understood as measuring electrical power, volume of gas, volume of water, or any other amount or volume of consumable value. Smart meters are installed by utility companies to measure the consumption of energy and to report on that consumption.

Other smart equipment, for instance Internet of Things (or IoT) devices or other sensors can be pre-installed or provided in the after-market, which also have the capability to measure energy consumption and to provide for energy consumption data.

With the increase of the number of sensors and smart devices providing consumption data, users get overwhelmed by the amount of data available.

Different to other types of data-driven market places, the energy market is unique. While the energy consumption as such is relatively predictable at an individual level and also within a peer group of individuals, other relevant aspects of the market are rather stochastic in nature. For instance, energy pricing, application of new technologies, provision of new tariffs and the impact of governmental regulation are not as predictable as the consumption data itself.

It is an object of the subject-matter to enable users getting an overview over consumption data from multiple end points in an easy to understand and intuitive way.

### BRIEF SUMMARY OF THE INVENTION

This object is solved according to exemplary embodiments of a method as disclosed herein, exemplary embodiments of a system as disclosed herein, as well as exemplary embodiments of a computer program product as disclosed herein.

It has been found that providing the consumption information to a user could be done using different types of communication channels. It has moreover been found that the communication channel for addressing a certain user may differ between users. Thus, it is proposed to extract and store information from previous exchange of consumption information in order to set a communication channel for transmitting the consumption information to a user.

Consumption data could be obtained from at least one data source. Data streams providing consumption data may be available from multiple end points, such as utilities, smart equipment, bills, home automation devices and the like. It has been found that the conversion, i.e. the feedback of a user, to communication of consumption information can be relevant for selecting a communication channel for a prospected transmission of consumption information.

Consumption data could relate to any type of consumable goods, in particular to electric energy, water, gas etc. In the following, when energy consumption is related to, it can be understood as any other type of consumable. Consumption data could be understood as meter readings from smart meters, billing information from utility bills, tariff information from utilities, consumption charts of historic consumption, performance reports of single sites, performance reports of multiple sites, real time consumption data, basic usage consumption data, demand response data, rebate and incentive data, procurement data, benchmark data and the like.

Data sources for consumption data (e.g. insights) as well as triggers may be:

Data from Utility Data Sources, which may cover the continuous, regular data feeds from various sources and captured in different databases. The data may be at least one of:

Invoice data, comprising at least one of Utility company, Contract number, Item (Electricity, Gas, Water, etc.), Invoice data, Usage, Costs, Payment due date,

Meter data from utilities, comprising at least one of Interval reading data for electricity, gas, water,

General utility alerts and information comprising at least one of Outage alerts, Price spike (peak pricing) information, Demand response event information,

Utility Tariff database data, comprising at least one of Electricity tariffs, Gas tariffs.

Other Data Sources may also provide consumption data as well as triggers may be at least one of:

Time of Day, Weather Data, Local temperature at location close to site, Wind speed at location close to site, Energy Usage Benchmark, Commodity trading price data, Wholesale electricity prices, Wholesale gas prices, Operative location data, e.g. Equipment data (HVAC, freezer, . . . ), Revenue related data (tickets, visitors, . . . ), Energy news data, etc.

In particular, meter readings, either online or stored as historic graphs could be provided from one data source. Other consumption data may be obtained from a monthly bill. A monthly bill may be scanned and consumption data, consumption prices and tariffs may be extracted therefrom. Extracting tariffs from a bill could be done according to the teaching of WO 2017/067579 A1, with a priority date of Oct. 20, 2015, assigned to the applicant, the content of which is incorporated herein in its entirety by reference thereto.

Extracting energy consumption information from a bill could be done according to the teaching WO 2013/138851 A1, with a priority date of Mar. 19, 2012, assigned to INVITCO NOMINEES PTY. LTD., the content of which is incorporated herein in its entirety by reference thereto.

By way of selecting a communication channel for transmitting the consumption information to a user, selected from a set of different communication channels, based on stored information extracted from previous exchange of consumption information, there is provided a dynamic, user-centric use and expense data platform providing the consumption information to the user. The transmission of the consumption information is based on automated data consolidation, analysis, and delivery duration. The transmission of the consumption information to the user may be done through various different channels. The channels could be, for instance, e-mail, voice mail, short message services, over-the-top messaging services, social network services and the like.

The method according to embodiments provides for different scenarios, which can be a regular bill review, a usage alert, an opportunity alert or the like. For instance, a user may trigger the method for a regular, for instance monthly bill review, approval and payment. Also, a quarterly spending review, a sustainability report, a performance review, target setting, usage monitoring, high usage alerts, voluntary energy audits and more could be triggered by the method. Also, new site set up and site closing, e.g. a link to utilities and measurement and verification of efficiency measures could be enabled using the claimed method.

The utility could trigger the method for informing the user about changes in energy cost, regional outages, upcoming constrains, demand response capabilities, new technologies, technology assessments, energy audits or the like.

The consumption data could be data provided from a meter, from a bill provided by the utility, data already extracted from a bill by a third party, sub meter data, equipment data, such as IoT devices, home automation devices or the like, and company business data, for instance information about a number of visitors, a number of transactions or the like.

There can be provided an ongoing monitoring process of utility related events. Events can be (but are not limited to): meter readings, receiving of an invoice (and for instance automatic extraction of consumption data from that invoice), alerts or customer related pieces of information from utility, information about a “peak pricing” event (from utility),

The algorithm analyses and assesses the regular and/or continuous data and information supplied and optimizes the amount, type, form and time of information that is provided to the end-user.

Information extracted from previous exchange of the consumption information could be information about opening (reading) rates of communications (views and/or) clicks, questions asked by users, notes and comments added by users, responses by users to questions or users activating certain response buttons, such as “thank you” or the like.

Consumption data could be obtained using APIs provided by utilities for sharing customer data electronically, automatic extraction of data from pdf or paper bills, readings or sub meter readings from meters, meter devices, sub meter devices, equipment with usage data monitoring, streams provided by utilities containing meter data.

It is proposed that the system monitors for new information from a variety of sources as well as for expected information. These information sources create events broadly named “positive triggers” and “negative triggers”.

Positive triggers may be events in which new consumption information related to a site is acquired or received by the system. Examples of positive triggers may be receiving monthly bills from a utility as expected. Another trigger might be a pricing signal. Meter readings may also be understood as positive triggers.

It may be possible to evaluate historic data and to obtain information about the frequency and or time consumption information is received. If new consumption information is received within the expected frequency and/or at the expected time, a positive trigger might be issued.

On the other hand, if consumption information is expected and not received, a negative trigger might be issued.

Users can receive and respond to communications by which the consumption information is transmitted using for instance web applications, mobile applications, interactions via messaging channels including SMS and over-the-top services, phones, tablets, computers and the like.

Once a positive or negative trigger is issued, information may be processed. Processing information may result in insights into consumption data.

The system processes the new information and triggers to create new information, also known as “insights”. It is proposed that every new piece of information is processed, regardless of the value of the insight, which will be evaluated at the next step. The result is a portfolio of insights for evaluation.

In addition to the creation of each insight, the system will create different formats of the insight designed for different communication channels. Broadly speaking, there will be both summary and lengthy versions of the same insights, and these insights do not compete with each other.

As an example, an energy manager expects a new monthly bill, which is a positive trigger, to be processed. Processing could be calculating the difference between the bill amount to the budgeted amount and determine if within expected variance. A brief and lengthy version of this insight are created by the system.

The brief version could be:

Got July 2017 bill for Store #123. Bill is 0.3% more than expected.

The lengthy version could be:

Hello, we received the July 2017 bill for Store #123. We scanned the bill for errors, and no mathematical errors were found and pricing is what is expected. The billed amount was $1234.56, which is 0.3% more than the expected budget for the time period.

Another example could be that a store manager expects to receive a daily meter reading, which is a positive trigger to be processed. However, no consumption data was received for the last 48 hours. Since the frequency of this consumption information is expected to be higher than it is, a new negative trigger is issued. Based on this trigger, two insights are created by the system.

The brief version could be:

No usage data received for Store #123 for past 48 hours. Check if meter requires attention.

The lengthy version could be:

Hello, we have received no usage data for your store within the past 48 hours. It is possible that the meter requires attention, or there is an issue with the utility receiving data. The internal meters for other equipment within the store still show usage information for the past 48 hours.

It has been found that the communication method of insights into consumption data can have different approaches. For instance, depending on the recipient, content, format, and/or timing the consumption information can be different. Depending on the recipient's need, the insight, e.g. content, format, and/or timing could be tailored. In order to provide for an optimal way to display insights into consumption information, it is proposed that information extracted from previous exchange of the consumption information is stored and then used for tailoring content, format and/or timing. It has been found that, for instance, a response to a transmission of the consumption information can be indicative, whether a user appreciated this communication or not. Driven by situational, contractual, historical, and/or user specific criteria, content, format and/or timing of the consumption information could be different. This allows for optimization of the conversation with the user. The user may actively respond to received information. This response can be extracted from a previous exchange of consumption information and stored for future selection of content, format and/or timing.

It has been found that content could, for instance, be the total amount of energy, the total price, the price per unit, tariff information, usage information, e.g. broken down to sites and the like, etc. Format could, for instance, be plaintext, a combination of text and tables, tables, charts, graphical representation of consumption information and the like. Timing could, for instance, be the day of a month, the hour of a day or the like.

Once a user receives consumption information, he may use it (select, retrieve, watch, read or the like). In addition, a user may confirm usage or may respond by asking questions. All this can be information extracted from the previous exchange of the consumption information. In case a user positively responds to a transmission, it seems to be obvious that the content, format and/or timing of this information have been useful. Within a learning loop, each time it is evaluated, which content, format, and/or timing the user responded to and in which way, i.e. positive, neutral or negative.

According to embodiments, it is proposed that this stored information extracted from the previous exchange of the consumption information comprises engagement measurements. Engagement measurements may, for instance, be a measurement of a conversion rate, a number of questions asked, a time gap between reception and usage of information, a number of views, a number of clicks, a type of a response, whether been positive or negative or the like. The higher the engagement, i.e. the better the information was received by a user, the more likely it is that the used content, format and/or timing was correct. Thus, within a learning loop, each time consumption information is transmitted and received by a user, the engagement measurement is re-evaluated.

According to embodiments, it is proposed that a set of different user roles is stored. User roles can, for instance, be energy manager, store/site manager, facility manager, environmental manager, bookkeeping, energy consultant, contractor or the like. Each of these user roles may require different types of consumption information extracted from consumption data. The energy manager may want to monitor and manage energy bills, identify energy saving opportunities and report results for compliance. A store/site manager may want to manage costs to ensure cash flow, ensure that his team follows his procedures, and wants to align implementation of measures. A facility manager wants to ensure building operations, check performance improvements and wants to understand drivers of performance. An environmental manager wants to identify energy conservation opportunities, track and report CO2 performance and wants to assess the effect of new energy technologies. Bookkeeping wants to track and forecast energy costs, ensure correctness of energy bills and wants to understand the bills for future investments. An energy consultant wants to audit his clients based on all available data, discover saving options and rebates and wants to track impact after implementation of measures. A contractor wants to provide fact based business cases, access rebate opportunities and wants to track the impact after implementation of his measures. These and other user roles could be stored within a set of different user roles.

Each user can be assigned to a user role. A communication channel and/or content and/or format and/or timing of transmission of the consumption information can be selected based on the user role. It is proposed that at least two, preferably all users within one user role are measured as peer group. The engagement measurement and the conversion rate of communications with users of a same peer group can be measured and extracted as information from the previous exchange of consumption information. Based on this extracted information, it can be evaluated, which communication channel, content, format and/or timing users in a certain peer group will appreciate with a high likelihood. Thus, based on engagement measurements with other users of a peer group, a user of that peer group could receive the communication in a content, format and/or timing and on a communication channel he is most likely to expect and appreciate.

According to embodiments, it is proposed that at least time and/or a date of a prospected transmission of the consumption information is extracted. Consumption information is assembled based on consumption data. Then, based on previous knowledge and on user settings, certain timing, e.g. a time of a day and a date to transmit this data can be prospected. However, the same type of information could be relevant in different communication channels, content and/or format a certain user based on timing. Thus, the communication channel, content and/or format of transmission of the consumption information can be selected based on prospected timing. It is possible to differentiate the communication channel, content and/or format of a transmission depending on the time and date the information is about to be transmitted.

A user may respond to received consumption information in different ways. For instance, the response channel, the response content and/or the response time could be selected by the user. A response channel may, for instance, be the same channel the information was received on, or a different channel. The response channels could be similar to the channels for the transmission of consumption information as mentioned above.

Response content can, for instance, be only information that the information was received, a positive or negative feedback, for instance, by clicking a respective button within the consumption information received, as well as response time, e.g. whether the response is immediate or with a certain time gap between reception and response. The response content can be extracted from an exchange of the consumption information. Also, the response content could be used as engagement measurement.

Based on the response of a user, a new transmission of consumption information can be tailored with respect to channel, content, format and/or timing or the like. Thus, the response content can be used as information extracted from the previous exchange of the consumption information. This enables a learning loop, where responses of users to certain types of communications are evaluated and used for future communications. Also, it is possible to evaluate responses for users within a same user role, such that new users are treated similar to other users with this user role without the need for any information about the user's individual behavior.

According to embodiments, on a per user level, a set of communication channels, a set of contents and/or a set of formats and/or a set of timings is provided. Thus, on a per user level, a multi-dimensional set of information is assembled. For each of the elements of each set, scoring values can be assigned.

Moreover, a scoring of an insight can be created. An insight may be understood as the consumption information. It may be possible that a score is created for urgency and importance, each. The score may be processed based on the initial goals of the user, the communication channels, and the feedback loops from the user on the value of the insights. As a starting point, the scoring process can be based broadly on the insight's importance and its urgency (similar to the “Eisenhower Matrix”). For instance, a score can be created using an Eisenhower Matrix.

The algorithm model for processing the score can have the form of the following:

SVₘ=f{CD₁, CD₂ . . . CDₙ}+f{TS₁, TS₂ . . . TSₙ}+f{UI₁, UI₂ . . . UIₙ}

where

SVₘ=scoring value of consumption information

CDₙ=value of consumption data

TSₙ=value of time sensitivity

UIₙ=value of user interaction from prior interactions

The scoring value model may determine the value of the consumption data, and if the scoring value exceeds a threshold, the consumption information can be evaluated on the appropriate communication channel and the amount of information.

Importance can be categorized in two categories, which are factual (i.e. high impact on the business or the specific role of the user) and personal (i.e. high impact based on the preferences of the user). Urgency can be categorized in two categories, which are factual (i.e. high urgency due to impact on the business, the role of the user, the business processes that are affected) and personal (i.e. high impact based on the preferences of the user). Using such a score, priorities can be to the insights and the subsequent communication to the user.

It is possible that default scoring values can be assigned to the elements of the sets. Default scoring values may, for instance, be dependent on the user role and on scoring values of a median user within a certain user role. Nevertheless, for each user, at least one element of at least one set can be changed depending on at least one of a response channel, a response content, or a response time extracted from previous exchange of the consumption information with that user.

Based on response information, at least one element of at least one set is assigned a scoring value. For instance, a response channel may have an effect on a scoring value of an element within the set of communication channels. A response content may have effect on a scoring value of an element within the set of contents, the set of formats and/or the set of timings. A response time may have effect on a scoring value of an element within the set of contents, the set of formats, and/or the set of timings.

According to embodiments, depending on a scoring value of elements within a set, one element of a set is selected for transmitting the consumption information to the user. Thus, by scoring the elements, a highest scored element can be identified. The highest scored element defines the channel, content, format and/or timing of transmission of consumption information to a user based on historic information of that user and/or of users within a similar or same user group.

Once a scoring value is high enough, i.e. an insight is confirmed as important enough and relevant to communicate, the system needs to determine how best to deliver the information efficiently and in an easy, user-friendly way, based on the previous scoring. If the scoring for the insight is high in both importance and urgency, then the system chooses the communication channel that ensures fastest reach and the version of the insight that is suitable for that channel.

For example, if the new insight is that a power outage is occurring at the store, then a text message (the communication channel for urgent insights, assuming a mobile phone is registered for the recipients) is used to deliver a brief version (the appropriate version of the insight). This can be delivered to both the store manager and the energy manager (the appropriate recipients of the insights).

A user's preference can influence the channel used for important insights.

For example, a user might complain that the system is “too chatty” (i.e., sends too many text messages), which would increase the threshold for a scoring value of an insight to achieve before using that channel. However, the insight might still be important to communicate to the user, so the system may send an email with the appropriate version of the insight.

The algorithm model for selecting a channel can have the form of the following:

CSₘ=f{SV₁, SV₂ . . . SVₙ}+f{ID₁, ID₂ . . . IDₙ}+f{TS₁, TS₂ . . . TSₙ}+f{UI₁, UI₂ . . . UIₙ}

where

CSₙ=channel scoring of consumption information

SVₙ=scoring value of consumption information

IDₙ=information density of the consumption information

TSₙ=value of time sensitivity of the consumption information

UIₙ=value of user interaction based on their role and from prior interactions/preferences

The channel scoring model may determine the priority of the consumption information and the best channel to deliver the consumption information to the end user.

Moreover, as short insight messages (via text, e-mail, or web-portal pop-ups) will offer the recipient the opportunity to go deeper on the respective matter (e.g. by offering links, or by texting back “tell me more”), the system will understand the level of depth that a specific recipient will want to have for a selected topic.

Insights might “queue up” for delivery to the user, and periodically the system will “clear the backlog” of insights by sending, i.e. by email, a brief version of several insights once within a certain period, i.e. a week or a month.

According to embodiments, it is proposed that depending on a received inquiry, a communication channel, a content, format and/or timing is selected for transmitting the consumption information to the user. When a user receives consumption information, he may respond by sending an inquiry. An inquiry can be a question, a complaint, a confirmation or acknowledgments. It is possible to semantically evaluate a user inquiry. Based on this evaluation, it can be evaluated, whether a received information was liked or not by a user. This may have effect on future communication to the user. In particular, the inquiry can be relevant for assigning a scoring value to at least one element within at least one set.

According to embodiments, the consumption data is extracted at least from a remote meter reading, a bill and/or a website and/or data extracted from the remote meter reading is compared with data extracted from the bill. Thus, it is possible to evaluate, whether a bill is correct or not based on actual meter readings.

In order to check the correctness of an energy bill, it is necessary not only to know the bill amount, but also the underlying amount of energy and the respective tariff. Thus, it is proposed that within extracted energy consumption data, at least an amount of energy and an assigned price is obtained and depending on the amount of energy and information about a tariff, the assigned price is checked. Thus, it is possible, to report errors within a bill.

According to embodiments, obtained remote meter readings are compared with historic meter readings. By doing that, it is possible to automatically evaluate whether actual meter readings are plausible. In case an actual meter reading deviates by a certain amount from historic meter readings, the consumption behavior must have changed. This could be an indication for either an incorrect meter reading or a changed use of a site. Such a deviation can be obtained by comparing the actual meter reading with historic meter readings. Depending on a deviation of the obtained remote meter readings from historic meter readings, consumption information can be transmitted to the user.

It has also been found that deviations in meter readings not necessarily depend on mistakes. It is also possible, to weigh the actual meter reading or the deviation. Weighing can be for instance be based on weather information, customer frequency, transaction frequency, changes in infrastructure, changes in equipment behavior or the like. These changes can be used to weigh the deviation and to thus evaluate, whether a deviation is out of norm or not. Only in the first case, a communication of consumption information could be issued.

According to embodiments, consumption information comprises information concerning a response channel and an interactive element to invoke the response channel. Embedded within the consumption information could be information about a response channel. Thus, when a user wants to respond, the respective response channel may already be available. Also, for instance a button could be embedded within the consumption information, which button the user can activate. Upon activation of this button, the response from the user could be sent.

A further aspect is an exemplary embodiment of a system as disclosed herein and an exemplary embodiment of a computer program as disclosed herein. These aspects can be combined with any of the above mentioned features.

The inventive method provides for an automated insight into consumption based on various data sets from different sources. This provides leverage for internal and external services and optimizes the number of available insights.

By evaluating inquiries and responses, the method may improve itself over time. By aggregating inquiries and responses from users within user groups it is possible to collect possible inquiries and to create adequate responses automatically.

The data concerning the consumption can be collected from different sources and stored. Then, the analysis on these data can be done to select the information required for the different types of information to be communicated to the user. The results of the analysis can be stored in a data repository and based on this stored information, different types of information can be aggregated to create the content, format and/or timing of the consumption information.

By monitoring inquiries and responses, conversion rates of single users, of peer users within a certain peer group and the like can be stored and used for adjusting the consumption information for future use. By providing this learning loop, the consumption information can be tailored for each user individually to give him the best insight possible into the consumption data.

### BRIEF DESCRIPTION OF THE SEVERAL VIEWS OF THE DRAWING

These and other aspects will become apparent from and in combination with at least one of the following figures. In the figures show:

FIG. 1 shows a schematic structure of implementing a method according to embodiments;

FIG. 2 shows a schematic structure showing different communication channels;

FIG. 3 shows an illustration of different templates for communicating energy consumption information;

FIG. 4 shows one embodiment for scoring elements of sets in a multi-dimensional scoring method;

FIG. 5 shows messages according to a first embodiment;

FIG. 6 shows messages according to a second embodiment;

FIG. 7 shows messages according to a third embodiment.

### DETAILED DESCRIPTION OF THE INVENTION

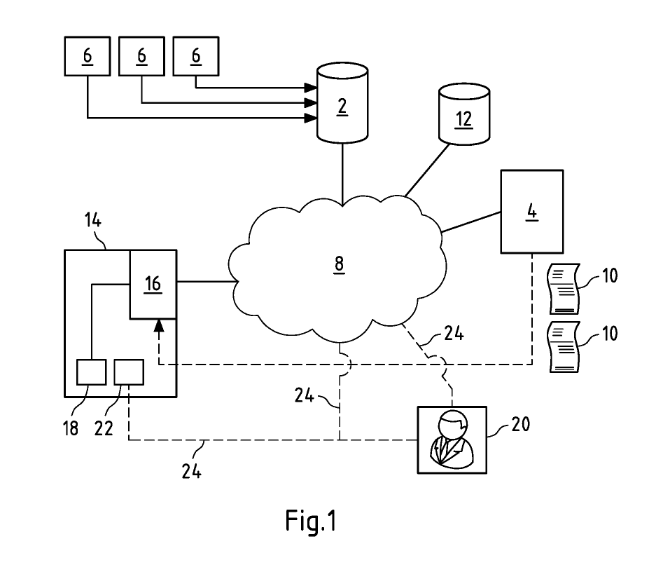

FIG. 1 illustrates a possible structure for implementing a method according to embodiments. Shown therein are various sources 2, 4, 12 providing energy consumption data. A first source 2 can be a centralized meter reading system, which is arranged for reading smart meters 6 on a regular or irregular basis. The source 2 may provide the meter readings from meters 6 online or in real time or in certain intervals to a billing facility 4, which also is a source of energy consumption data. Source 2 may provide an API, by which the meter readings can be accessed using, for instance a wide area network, such as the internet 8.

Billing facility 4 may provide for bills 10 to customers. A bill 10 can also be a source of energy consumption data. Billing facility 4 moreover provides for an API for accessing billing data of the bills 10. This can also be, for instance, a website where remote access via the wide area network 8 is possible.

A tariff engine 12 may also be provided, which provides for an API for accessing tariff data using wide area network 8.

More sources of data 2, 4, 12 may be used by a system 14 according to embodiments. The system 14 is arranged for transmitting energy consumption information to a user. Within system 14, there is provided interface 16 which is arranged for accessing the various sources 2, 4, 10, 12 through wide area network 8.

For evaluating the energy consumption data obtained through interface 16, an evaluation device 18 is provided.

In a first step, within evaluation device 18, based on input information via interface 16, triggers might be created, which can be positive or negative triggers. Expected information may create positive triggers, new information may create positive triggers and information not received but expected may create negative triggers.

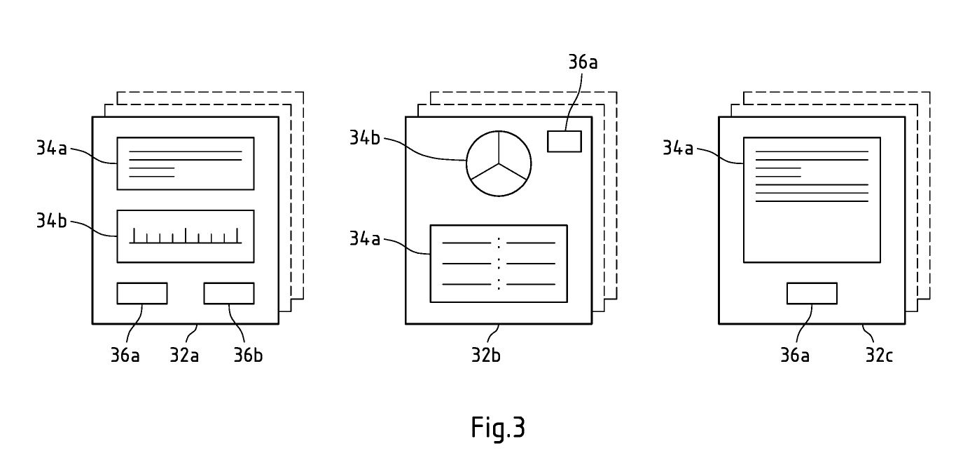

Then, the evaluation device 18 may extract from the energy consumption data energy consumption information. The extracted energy consumption information can be stored and implemented into various templates, as will be described in conjunction with FIG. 3. For instance, in case a trigger is create, the evaluation device 18 may create from the extracted consumption information insights, which may be, for instance, brief and lengthy, and for a respective communication channel, a respective format of an insight might be chosen. Then, for each insight a scoring can be created, where a scoring can have at least two values, one for urgency and one for importance.

Depending on the scoring value, it may be filtered, if an insight is send to a user or not, and over which communication channel.

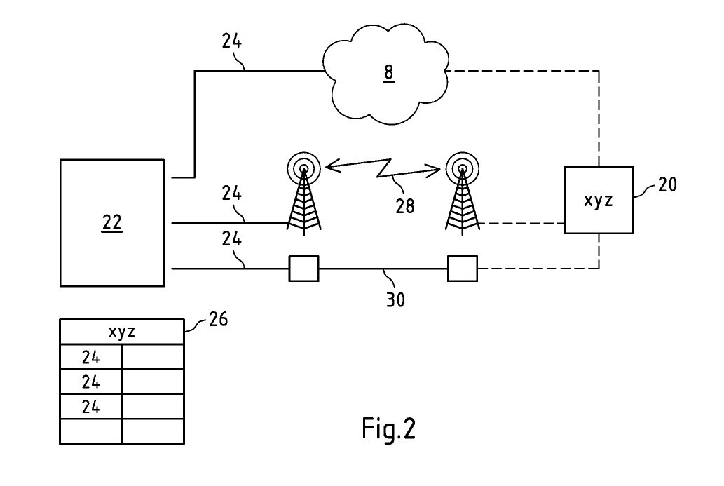

In particular, based on the energy consumption information and user settings, a communication channel, as illustrated in FIG. 2, can be selected for communicating the energy consumption information to a user 20.

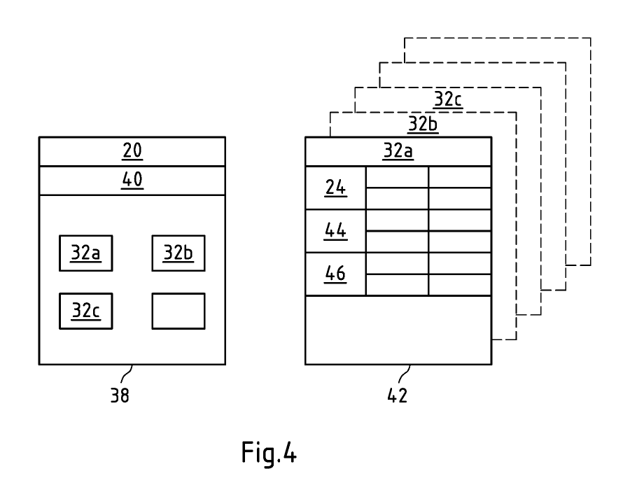

Each user can be assigned various sets of parameters as will be described in FIG. 4 for tailoring the communication parameters with this user. Depending on the selected communication channel, a communication interface 22 can be arranged for establishing communication channels 24 with the user 20.

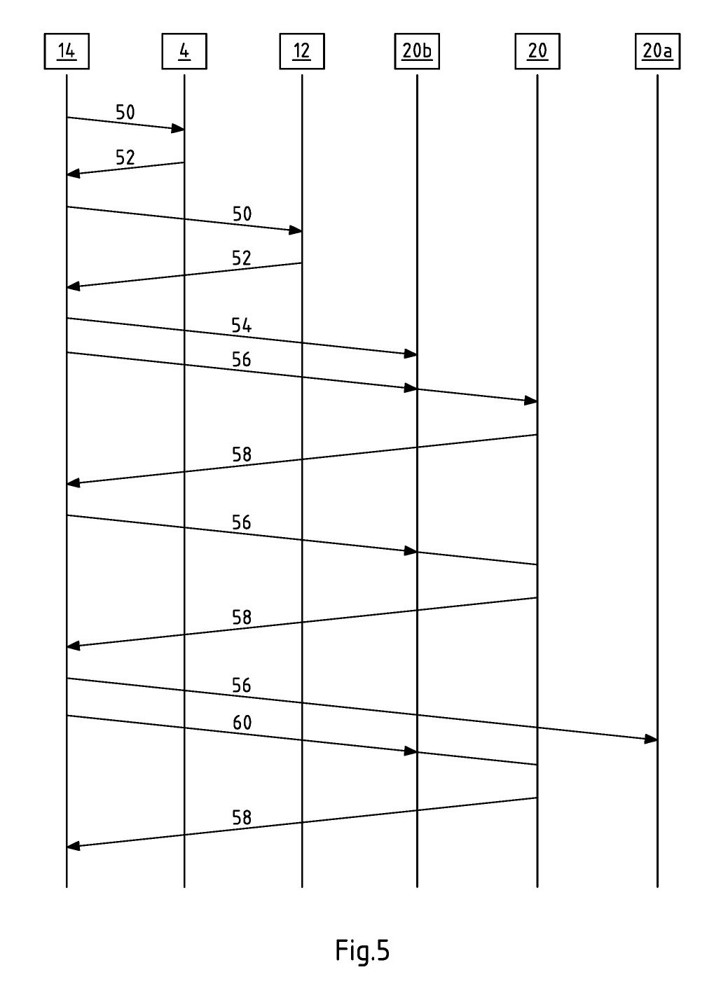

The selection of the communication channels 24 to communicate with the user 20 may depend on information extracted from previous exchange of the energy consumption information. Information extracted from previous exchange will be described in conjunction with FIGS. 5-7.

FIG. 2 illustrates the communication interface 22, which uses user database 26 for establishing communication channels 24 with a user 20. For each user there can be a user dataset within the database 26. Within this user dataset, for each user 20 there is provided, inter alia, a set of possible communication channels 24, and each communication channel 24 is assigned a scoring value. This scoring value for each of the communication channels 24 may depend on an engagement measure for this user. Engagement of a user 20 may be obtained by evaluating user reactions to communications, i.e. views, clicks, responses, inquiries etc., which are detected in response to a received communication from the communication interface 22.

The first communication channel 24 may be via the wide area network 8, for instance the internet. Another communication channel 24 may be a mobile communication network 28. A further communication channel 24 may be a hard wired channel 30. Each of the channels 24 may allow for bidirectional communication between communication interface 22 and user 20.

It is to be understood that a user 20 may have communication devices of different kinds and that different users 20 may have different types of communication devices. Depending on the communication device(s) of a user 20, which communication device(s) can be stored in user dataset 26, different kinds of communication channels 24, contents, formats or the like could be selected.

FIG. 3 shows different formats 32a-c for providing insights, e.g. content relating to the energy consumption data to the user 20.

For instance, a first format 32a may comprise textual and visual information 34a, 34b. In addition, interactive elements 36a, b, such as buttons can be provided within format 32a. For instance button 36a may be assigned to a positive feedback and button 36b may be assigned to a negative feedback.

Thus, when a user receives energy consumption information embedded within format 32a, he may interact with communication interface 22 and thus the system 14 through the interactive elements 36a, b. Depending on the user response, a scoring value for the communication channel and/or a scoring value for the format and/or a scoring value for the content 34a, 34b and/or a scoring value for the timing for that particular user and may be changed.

As can be seen in FIG. 3, various formats 32a-c are provided. Moreover, it may be possible to fill in the formats 32a-c with content, using the obtained energy consumption data for providing energy consumption information. A set of different formats 32a-c may be stored in a data repository. It may be possible that for each user 20 a respective set of formats may be created and stored for future use.

FIG. 4 illustrates a scoring for a certain user. As is illustrated in FIG. 4 for instance a dataset 38 for a user 20 may be provided. Within this data set 38, a user role 40 out of a set of different user roles may be assigned to the user 20. Moreover, different formats out of the formats 32a-c could be assigned to the user 20, indicating that the user shall receive the consumption information within one of these formats 32a-c.

In addition, for each of assigned formats 32a-c a multi-dimensional dataset 42 may be stored. Within this multi-dimensional dataset 42 respective sets like communication channel 24, timing 44, content 46 and/or the like may be stored for each of the different formats 32a-c. For each set at least two elements can be provided, and each of the elements can have a scoring value. The scoring values for communication channel 24, timing 44 and content 46 and any other communication parameter may be obtained from previous communications with the user and/or users within the peer group. This information extracted from previous energy consumption information is illustrated in FIG. 5-7.

FIG. 5 illustrates the communication between system 14, billing facility 4, tariff engine 12, user 20, a bookkeeping 20a of user 20 and a website 20b of user 20.

On a regular basis, the system 14 may poll 50 billing information from billing facility 4. Billing facility 4 may return 52 billing information. This may, for instance be a bill in pdf-format. This may also be an access code for accessing a website, where billing information is available, e.g. using an API.

From the energy consumption data within the returned 52 data, the system 14 may extract tariff information. Based on this tariff information, the system 14 may poll 50 tariff engine 12, whether there are other tariffs which fit better the user 20 needs. Tariff engine 12 may return 52 such information.

With the extracted energy consumption information from the data obtained from billing facility 4, the system 14 may populate 54 the website 20b. Moreover, for instance via an over-the-top (OTT) communication channel, system 14 may transmit 56 the energy consumption information, for instance within one of the formats 32a-c. The formats 32a-c may also be understood as reports. The population 54 may also be done using one of reports 32a-c.

The user 20 may evaluate the received report 32a-c and may, for instance, use one of the interactive elements 36a-b for responding 58 to system 14. Moreover, the user 20 may formulate an inquiry which may also be included in the response 58. The inquiry may contain textual information, e.g. what the user wants system 14 to do with the information or if the information was useful or if there is additional information or the like. For instance, this textual information may be “send me the report by mail” or “give me more detail information” or “don't send me this report again”. The communication channel 24 for the response 58 is not necessarily the same communication channel 24 by which the report was transmitted 56.

The system 14 analyses the response 58 and may formulate and create a new report 32a-c depending on the user inquiry 20.

Moreover, system 14 may evaluate, whether this information was useful for the user 20. Based on this evaluation, as is illustrated in FIG. 4, a scoring value for the communication channel 24, the timing 44, the content 46 and the report 32a-c itself can be created. In particular, the time lag between the transmission 56 and the response 58 may be indicative of a scoring value for timing 44. The use of an interactive element 36a, b, for instance indicating whether the information was useful or not, could be used for scoring the content 46. The communication channel by which the response 58 is received can be used for scoring the communication channel 24.

After having scored the various parameters in various dimensions, a newly created report 32 can be transmitted 56 to the user. Within this report 32, for instance a question whether the bill can be processed by accounting can be included and within a response the user 20 can clear the bill or not.

Again, based on the response, e.g. the response channel 24, the timing, the content of the response and the like, scoring values can be assigned to the respective report 32. Based on clearance, the system 14 may transmit 56 a new report 32 to an accounting department 20a, which processes the bill.

In addition, the system 14 may inquire 60 the user 20 about the usefulness of the previous communication and based on a response 58, the scoring of the communication can be done in the way described above.

By evaluating the responses 58 to transmissions 56 and inquiry 60, which may contain reports 32, each report 32 for each user 20 and the respective elements within the sets can be given scoring values such that within the next communication, the scoring value can be used to select the most suitable format 32 on the most suitable communication channel 24 with the most suitable content 46 at the most suitable timing 44. Thus, the system may learn who and when a report 32 was read. Moreover, the system 14 may learn, which communication channel 24 is preferred by user 20. By obtaining information from various sources 4, the reports 32 may be populated with additional data, which can be useful for the user 20.

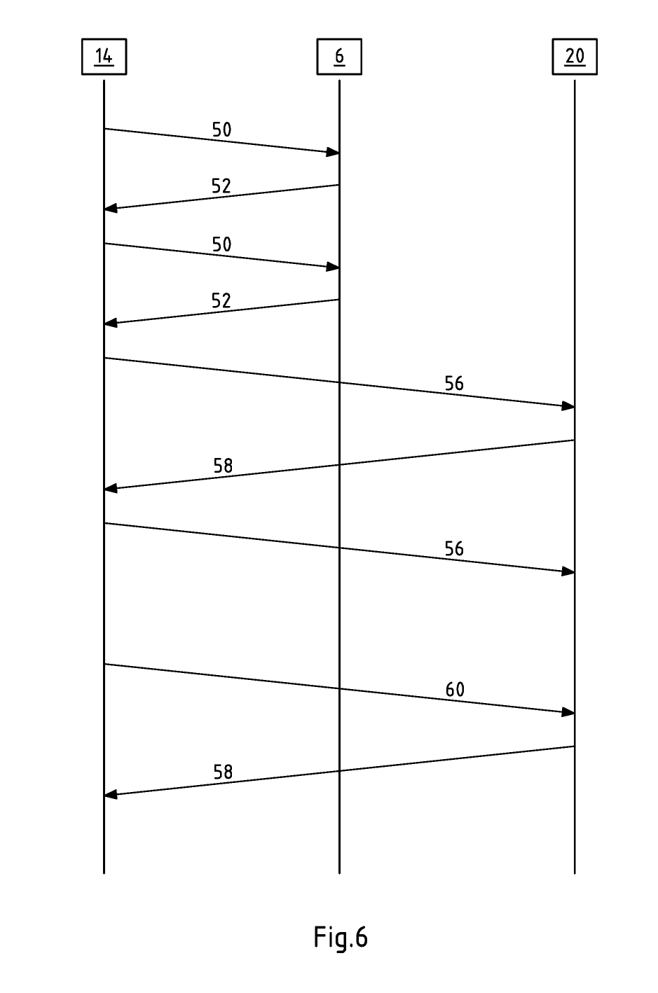

FIG. 6 illustrates a further scenario where system 14 polls on a regular basis a meter 6 and meter 6 returns 52 meter values. Based on the returned meter values (energy consumption data), the system 14 evaluates the consumption and compares it with usage profiles for the respective user 20.

The actual usage of energy can be weighted using, for instance, weather information, transaction information, guest information and the like. The weighing can be done to normalize the consumption data. In case the system 14 detects an unusual event or unusual consumption, system 14 may sent 56 a report 32 to user 20, indicating the deviation in use. Moreover, within this report 32, the system may ask user 20 whether he was aware of this deviation and whether he found this information useful. User 20 may return a response 58 to the system 14 answering these questions.

Based on the returned 58 content and its communication channel, the previously transmit 56 report can be scored in various dimensions, i.e. the elements within the sets. In addition, system 14 may provide for a report 32 indicating next steps to be taken in a transmission 56 to user 20.

Eventually, system may inquire 60 the user 20 about the usefulness of the information and may evaluate the respective response 58. For this user 20 a scoring value of the communication channel, the report, the content, the timing and the format could be obtained.

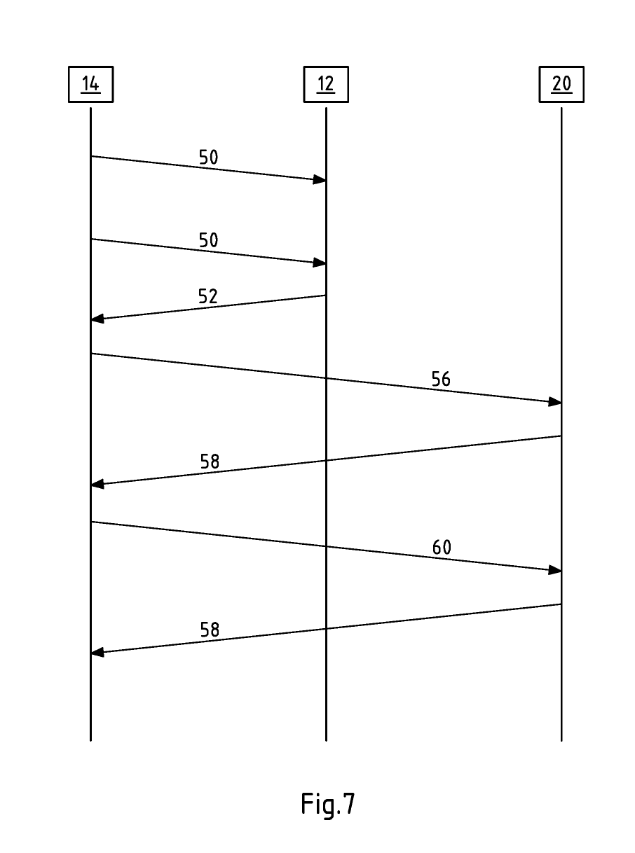

A further embodiment is illustrated in FIG. 7. In this embodiment, system 14 may, on a regular basis, poll 50 tariff engine 12. Tariff engine 12 may return 52 tariff information.

System 14 may evaluate the returned 52 tariff information and may detect that a certain tariff may be more suitable for a user than his actual tariff

Based on these findings, the system 14 may create a new report 32 indicating to the user 20 an opportunity to change the tariff. This new report 32 can be transmitted 56 to the user 20. Within the report 32 indicating the opportunity, interactive elements 36a, b may be provided. These interactive elements may, for instance, indicate “yes choose new tariff” or “no don't choose new tariff”. Depending on the response 58 by user 20, system 14 may automatically reach out to the utility per mail to change tariff

If the response 58 was negative, the system 14 will score the report 32 in a way indicating that new tariff information is not helpful for the user 20. However, system 14 may inquire user 20 about the reason why the user 20 neglected this opportunity and based on the response 58, system 14 will adapt the scoring for reporting new opportunities.

Thus, the system gets knowledge about the user interests and the timing when for instance new tariff information shall be sent to user 20.

By receiving a positive interaction in a response 58, a scoring value of at least one element can be increased by one. When receiving in a response 58 a negative interaction, a scoring value of at least one element can be decreased by one. A non-response 58 may account for a lesser decrease in a scoring value than an actual negative response 58.

Moreover, a format 32 can be forced to be transmit 56 to the user 20 by having default scoring values for certain reports, which cannot be overruled. These forced reports 32 can be based on a user set scoring value. Thus, users can override the automatic scoring and request reports 32 for certain information irrespective of the responses 58 thereto.

By means of the inventive method, energy consumption information is provided to users in a more tailored way, enabling users to react to changes in energy data more specifically.

All references, including publications, patent applications, and patents cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) is to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

### REFERENCE SIGNS

2 source
4 billing facility
6 meter
8 WAN
10 bill
12 tariff engine
14 system
16 interface
18 evaluations
20 user
22 communication device
24 communication channel
26 user data base
28 mobile communication network
30 hard wired channel
32 format/report
34a textual information
34b visual information
36a,b interactive element
38 data set
40 user roles
42 data set
44 timing
46 content
50 poll
52 return
54 populate
56 transmit
58 response
60 inquiry

1) A method for transmitting energy consumption information to a user comprising,
obtaining consumption data from at least one source,
extracting consumption information from the obtained consumption data, and
transmitting the extracted consumption information to the user,
wherein at least a communication channel for transmitting the consumption information to a user is selected from a set of different communication channels based on stored information extracted from previous exchange of the consumption information.

2) The method of claim 1, wherein content and/or format and/or timing of the consumption information is selected based on the stored information extracted from the previous exchange of the consumption information.

3) The method of claim 1, the stored information extracted from the previous exchange of the consumption information comprises engagement measurements.

4) The method of claim 1, wherein a set of different user roles is stored and that a user is assigned to at least one of the user roles and that the communication channel and/or content and/or format and/or timing of transmission of the consumption information is selected based on the user role.

5) The method of claim 1, wherein at least time and/or date of a prospected transmission of the consumption information is extracted and that the communication channel and/or content and/or format and/or timing of transmission of the consumption information is selected based on the time and/or date.

6) The method of claim 1, wherein at least one of a response channel, a response content or a response time is extracted from previous exchange of the consumption information and used as information extracted from the previous exchange of the consumption information

7) The method of claim 1, wherein on a per user level, a set of communication channels, a set of contents and/or a set of formats and/or a set of timings is provided and that depending on at least one of a response channel, a response content or a response time extracted from previous exchange of the consumption information, elements of a respective set are assigned scoring values.

8) The method of claim 1, wherein, depending on a score of an element within a set, an element of a set is selected for transmitting the consumption information to the user.

9) The method of claim 1, wherein depending on a received inquiry the communication channel and/or content and/or format and/or timing of transmission of the consumption information to the user is selected and/or that depending on a received inquiry an element of a at least one set is assigned a scoring value.

10) The method of claim 1, wherein the consumption data is extracted at least from a remote meter reading, an bill and/or a website and/or that data extracted from the remote meter reading is compared with data within the bill.

11) The method of claim 1, wherein within extracted consumption data, at least an amount of energy and an assigned price is obtained and depending on the amount of energy and information about a tariff of the user, the assigned price is checked.

12) The method of claim 1, wherein obtained remote meter readings are compared with historic meter readings and depending on a deviation of the obtained remote meter readings from historic meter readings consumption information is transmitted to the user, wherein in particular the deviation is weighted using environmental data, such as weather data.

13) The method of claim 1, wherein consumption information comprises information concerning a response channel and an interactive element to invoke the response channel.

14) A system arranged for transmitting consumption information to a user comprising,
an interface device arranged for obtaining consumption data from at least one source,
an evaluation device arranged for extracting consumption information from the obtained consumption data, and
a communication device arranged for transmitting the extracted consumption information to the user,
wherein the communication device is arranged such that at least a communication channel for transmitting the consumption information to a user is selected from a set of communication channels based on results of the evaluation device evaluating stored information extracted from previous exchange of the consumption information.

15) A computer program product comprising instructions for causing a processor to transmitting consumption information to a user comprising the steps:
obtaining consumption data from at least one source,
extracting consumption information from the obtained consumption data, and
transmitting the extracted consumption information to the user,
wherein at least a communication channel for transmitting the consumption information to a user is selected from a set of communication channels based on stored information extracted from previous exchange of the consumption information.
